(19) United States
(12) Patent Application Publication
(10) Pub. No.: US 2008/0057281 A1
(43) Pub. Date: Mar. 6, 2008

(54) CORROSION RESISTANT AND HIGH SATURATION MAGNETIZATION MATERIALS

(75) Inventors: Mark Thomas Kief, Lakeville, MN (US); Steven Carl Riemer, Minneapolis, MN (US); Vladyslav Alexandrovich Vas'ko, Apple Valley, MN (US); Ibro Tabakovic, Edina, MN (US)

Correspondence Address: SHUMAKER & SIEFFERT, P. A., 1625 RADIO DRIVE, SUITE 300, WOODBURY, MN, 55125, US

(73) Assignee: Seagate Technology LLC, Scotts Valley, CA (US)

(21) Appl. No.: 11/927,194

(22) Filed: Oct. 29, 2007

Related U.S. Application Data
(63) Continuation-in-part of application No. 11/479,604, filed on Jun. 30, 2006.

(51) Int. Cl. B32B 7/02; C22C 38/00; C23C 14/14

(52) U.S. Cl. 428/216; 420/82; 427/531

(57) ABSTRACT

An alloy with the formula Fe_{A}Co_{B}M_{C}, where M includes at least one element of Rh, Ru, Pt, Pd, Os, and Ir, and where 48≦A<60, 30≦B≦50, and 5<C≦20 or where 50≦A≦70, 35<B≦50, and 5<C≦20. In the formula, A+B+C=about 100 at %. The alloys resist corrosion and have a high saturation magnetization. The materials, which may be provided as thin films, are suitable for use as write pole materials in recording heads for magnetic media in data storage devices.

This application is a continuation-in-part of application Ser. No. 11/479,604, filed Jun. 30, 2006, which is incorporated by reference herein in its entirety.

### TECHNICAL FIELD

The present disclosure is directed to corrosion resistant materials with a saturation magnetization, as well as electronic devices using the materials. The materials, which may be provided as thin films, are suitable for use as write pole materials in recording heads for magnetic media in data storage devices.

### BACKGROUND

Magnetic media recording heads (which perform both reading and writing functions) detect and modify the magnetic properties of the surface of the magnetic media in a data storage device. In some data storage devices such as, for example, hard disc drives, the recording heads are positioned close to a rotating, air bearing surface (ABS) of a disc of magnetic media and fly above the disc on a cushion of air. Because of the high disc rotation speeds, information density, and close tolerances within the drive, the interior of hard disc drives should be extremely clean and free of contaminants. Nevertheless, some contaminants can accumulate within the drive from the external environment, from other components within the drive, or from the manufacturing process used to make the drive components. These contaminants may corrode the components of the drive, which can result in catastrophic failure of the recording head.

Magnetic media heads with a high saturation magnetization (also known as saturation moment, saturation induction or Bₛ) are often desired because a high saturation magnetization facilitates the making of drives (or other magnetic media) with higher data density and higher access and record times. Alloys of FeCo and FeCoNi provide a very high Bₛ(>2.0 Tesla (T)) near and above room temperature, but process and operational conditions can result in corrosion and failure of magnetic media recording heads made from these materials. To control corrosion, protective layers such as diamond-like carbon (DLC) may be applied to the head surface, or the alloys may be doped with additional elements such as Cr. However, these protective layers and dopants typically result in significantly diminished Bₛ, which in turn causes reduced magnetic recording head performance in such read/write functions as overwrite (OVW) or bit error rate (BER).

### SUMMARY

In one aspect, the present disclosure is directed to a corrosion resistant ferromagnetic alloy suitable for use as a thin film, such as for a write pole material in a magnetic media recording head, as well as to magnetic media recording heads containing the corrosion resistant alloy.

In one embodiment, an alloy has a formula Fe_{A}Co_{B}M_{C}, where M includes at least one element of Rh, Ru, Pt, Pd, Os, and Ir, and 48≦A<60, 30≦B≦50 and 5<C≦20. In general, A+B+C=about 100 atomic percent (at %).

In another embodiment, an alloy has a formula Fe_{A}Co_{B}M_{C}, where M includes at least one element of Rh, Ru, Pt, Pd, Os, and Ir, and 50≦A≦70, 35<B≦50 and 5<C≦20. In general, A+B+C=about 100 at %.

In another aspect, this disclosure describes processes of forming the alloy and applying it to substrates, such as magnetic media heads. The corrosion resistant alloy provides significant corrosion resistance while simultaneously maintaining a high saturation magnetization (Bₛ) that approaches the saturation magnetization of pure FeCo and FeCoNi alloys. The corrosion resistance is advantageous because, for example, it helps avoids deterioration in the drive head during manufacture or during use. The high saturation magnetization facilitates the production of high density drives that have superior performance features such as, for example, high density read/write functions.

In one embodiment, a process includes depositing metals selected from a group including Fe, Co, Rh, Ru, Pt, Pd, Os, and Ir to form an alloy with a formula Fe_{A}Co_{B}M_{C}, where M includes at least one element of Rh, Ru, Pt, Pd, Os, and Ir, and 48≦A<60, 30≦B≦50 and 5<C≦20. In general, A+B+C=about 100 at %. In some embodiments, the metals are deposited using a physical vapor deposition method (e.g., sputter deposition) or an electroplating method.

In another embodiment, a process includes depositing metals selected from a group including Fe, Co, Rh, Ru, Pt, Pd, Os, and Ir to form an alloy with a formula Fe_{A}Co_{B}M_{C}, where M includes at least one element of Rh, Ru, Pt, Pd, Os, and Ir, and 50≦A≦70, 35<B≦50 and 5<C≦20. In general, A+B+C=about 100 at %. In some embodiments, the metals are deposited using a physical vapor deposition method (e.g., sputter deposition) or an electroplating method.

In yet another aspect, the present disclosure describes applications of the alloy. In one application, a magnetic read/write head includes a write pole including a thin film. The thin film includes an alloy with a formula Fe_{A}Co_{B}M_{C}, where M includes at least one element of Rh, Ru, Pt, Pd, Os, and Ir, where 48≦A<60, 30≦B≦50 and 5<C≦20. In general, A+B+C=about 100 at %. In another application, a thin film of a magnetic read/write head includes an alloy with a formula Fe_{A}Co_{B}M_{C}, where M includes at least one element of Rh, Ru, Pt, Pd, Os, and Ir, and 50≦A≦70, 35<B≦50 and 5<C≦20. In general, A+B+C=about 100 at %.

The above summary of the present invention is not intended to describe each disclosed embodiment or every implementation of the present invention. The figures and the detailed description that follow more particularly exemplify these embodiments.

### BRIEF DESCRIPTION OF DRAWINGS

The invention may be more completely understood in consideration of the following detailed description of various embodiments of the invention in connection with the accompanying drawings, in which:

FIGS. 1 and 2 are diagrammatic and system block views, respectively, of an exemplary fixed disc drive for which embodiments of the alloy are useful.

FIG. 3 is a cross-sectional view of a read/write head taken along a plane normal to an air bearing surface (ABS) of the read/write head.

FIG. 4 is a plot depicting the saturation magnetization (Bₛ) of various FeCoM alloys, where M is one of Pd, Pt, or Ru.

FIG. 5A is a chart depicting the corrosion potential (E_{Corr}) of various FeCoM alloys.

FIG. 5B is a chart depicting the corrosion current density (I_{Corr}) of various FeCoM alloys.

FIG. 5C is a chart depicting the corrosion potential (E_{Corr}) of various FeCoM alloys.

FIG. 5D is a chart depicting the corrosion current density (I_{Corr}) of various FeCoM alloys.

FIG. 6 is a chart depicting the corrosion current density (I_{Corr}) of various FeCoM alloys when exposed to a potential of +0.1V versus a saturated calomel electrode (SCE).

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

In one aspect, this disclosure is directed to an alloy including Fe, Co and a metal dopant M selected from a group including Rh, Ru, Pt, Pd, Os, and Ir. In some embodiments, more than one metal dopant M may be included in the alloy. The relative ratios of FeCo and the at least one metal dopant M are selected to provide minimal saturation magnetization loss and high noble corrosion properties to the alloy.

In one embodiment, an alloy in accordance with the present invention has a general formula Fe_{A}Co_{B}M_{C}, where M is at least one of Rh, Ru, Pt, Pd, Os, and Ir, and where 48≦A<60, 30≦B≦50 and 5<C≦20. In general, A+B+C=about 100 at %. Where more than one metal dopant M is included in the alloy, the total atomic percent C of the dopants M in the alloy still remains between about 5 and 20. In another embodiment, an alloy has a general formula Fe_{A}Co_{B}M_{C}, where M is at least one of Rh, Ru, Pt, Pd, Os, and Ir, and where 50≦A≦70, 35<B≦50 and 5<C≦20, and where A+B+C=about 100 at %.

Preferred dopant metals M in the formula for both embodiments include Rh, Ru, Pt, and Pd, and most preferred dopant metals M include Rh and Pt. It has been found that in both embodiments, when 5<C≦20 at %, the corrosion resistance of the alloy is improved compared to conventional FeCo and FeCoNi alloys, while at the same time, the saturation magnetization Bₛ, is maintained at a sufficiently high level (greater than about 2.0 Tesla (T)) for many applications, including magnetic write poles.

For example, alloys with the general formula Fe_{A}Co_{B}M_{C}, where M is at least one of Rh, Ru, Pt, Pd, Os, and Ir, wherein, in at %, 55≦A<65, 35≦B≦40 and 5<C≦10, have very high saturation magnetizations of Bₛ>2.2 T. These alloys also exhibit improved corrosion properties compared to conventional FeCo and FeCoNi alloys.

In another example, alloys with the general formula Fe_{A}Co_{B}M_{C}, where M is at least one of Rh, Ru, Pt, Pd, Os, and Ir, wherein, in at %, 55≦A<65, 35≦B≦40 and 8<C≦12 have very high saturation magnetizations of Bₛ>2.2 T and improved corrosion properties compared to conventional FeCo and FeCoNi alloys.

A small percentage of impurities may be present in the alloy due to the method of forming the alloy, impure metal sources, or other reasons. Preferably, the alloy of the present invention includes less than about 0.20 at % of impurities, particularly any of H, N, O, S, Cl, F, and C. In one embodiment, the alloy includes about 0.05 at % to about 0.10 at % of impurities. For the formula A+B+C=about 100 at %, about 100 at % is not exact and may be adjusted to account for a small percentage of impurities, typically less than about 0.20 at %. For example, where the alloy comprises 0.20 at % of impurities, A+B+C=99.8 at %. For ease of description, “about 100 atomic percent” is used to describe 100 atomic percent with the presence of a small percentage of impurities, if present.

The corrosion resistant alloys may be prepared using a wide variety of techniques such as, for example, electroplating deposition and physical vapor deposition. The alloys are preferably prepared using physical vapor deposition techniques, particularly vacuum vapor deposition from pure metal sources, such as, for example, sputter deposition or evaporation. The method of making the alloys is preferably selected to eliminate or substantially minimize impurities within the materials, particularly any of H, N, O, S, Cl, F, and C. For example, in one method, the alloy of the present invention is sputter deposited from ultra pure metal targets to form a magnetic thin film including less than about 0.20 at % of impurities. The ultra pure metal targets may be elemental or alloy targets.

The alloy of the present invention may be used in any application requiring very high saturation magnetization (Bₛ) and good corrosion properties. Examples include, but are not limited to, write poles (also known as main poles) and/or shields for read/write heads for magnetic media used in data storage devices, magnetic thin film devices such as inductors and isolators, MEMS, and other spintronic devices, shields in devices other than read/write heads for shielding an element from stray magnetic fields, and other magnetic thin film applications.

When the alloy is used in a write pole of a disc drive, the alloy may be formed as a thin film. The thickness of the film may vary widely depending on the intended application and the structure of the read/write head. In one embodiment, the film is about 0.005 microns (μm) to about 0.5 μm thick. In another embodiment, the film is about 0.2 to 0.5 μm thick.

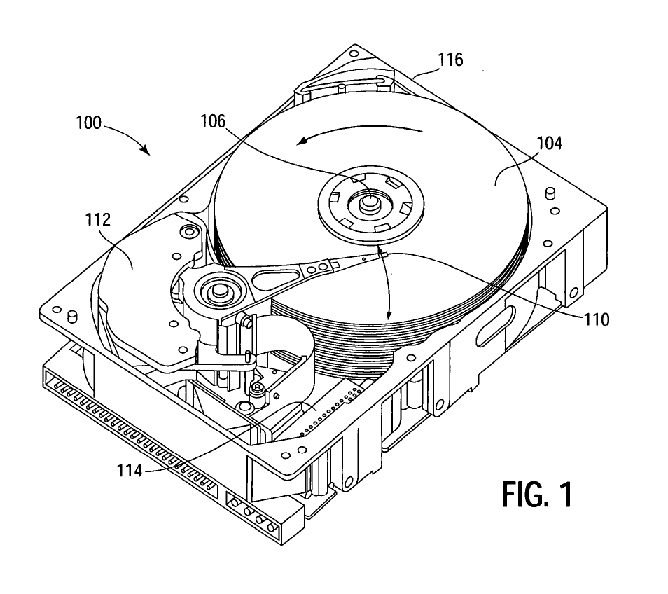

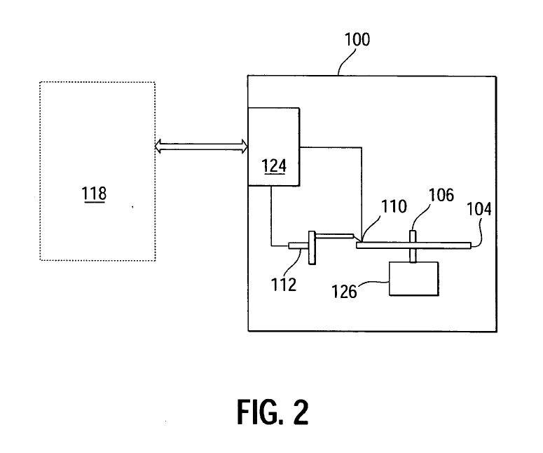

Referring now to FIGS. 1-2, a diagrammatic view of a disc drive 100 is shown that includes magnetic disc 104, spindle 106, spindle motor 126, magnetic head 110, actuator 112, and board electronics 114. The disc 104 is fixed about the spindle 106, which is coupled to the spindle motor 126. When the spindle motor 126 is energized, the spindle motor 126 causes the spindle 106 and disc 104 to rotate. When the disc 104 rotates, the magnetic head 110 flies above (or in some cases, below) the disc 104 on thin films of air or liquid, which carry the magnetic head 110 for communicating with the respective disc 104 surface. The surface of the magnetic head 110 adjacent to the thin film of air or liquid is commonly referred to as the ABS.

The board electronics 114 include a disc controller 124. The controller 124 is typically a microprocessor, or digital computer, and is coupled to a host system 118, or another drive controller which controls a plurality of drives. The controller 124 operates based on programmed instructions received from the host system. In particular, the controller 124 receives position information indicating a location on the disc 104 to be accessed. Based on the position information, the controller 124 provides a position signal to the actuator 112, which is coupled to the magnetic head 110. The actuator 112, therefore, moves the magnetic head 110 radially over the surface of the disc 104. The controller 124 and actuator 112 operate in a known manner so that the magnetic head 110 is positioned over the desired location of the disc 104. Once the magnetic head 110 is properly positioned, the magnetic head 110 performs a desired read or write operation.

In one application, the alloys described in this disclosure may be used in any magnetic head 110 design that is suitable for recording on a data storage device, including perpendicular recording heads, longitudinal recording heads, and the like. The following description will serve only as an example of a recording head design in which the alloys may be suitable, and is not intended to be limiting.

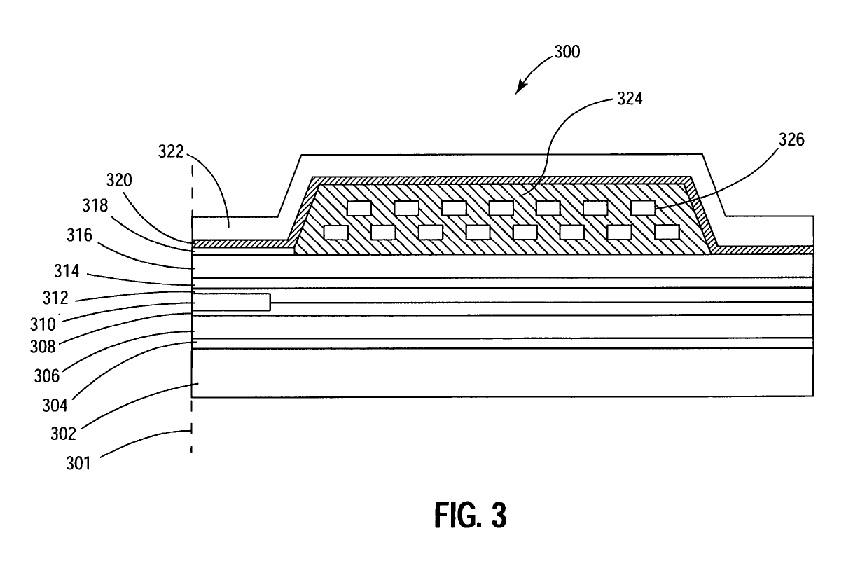

The magnetic head 110 design may be, for example, a merged read/write head, which records information in multiple circular tracks on the respective disc surfaces and reads information therefrom. FIG. 3 is a cross-sectional view of an exemplary merged read/write head 300 taken along a plane normal to the air bearing surface (ABS) 301. The read/write head 300 is fabricated by depositing several layers through processes such as electroplating deposition and photolithography, physical vapor deposition (PVD), sputtering, vacuum vapor deposition, evaporation or the like. Typically, thin film layers are deposited to form the read portion of the merged read/write head 300 after which additional thin film layers are deposited to form the write head portion.

A bottom shield seed layer 304 is formed by deposition on a substrate 302. A bottom shield layer 306 is deposited on bottom shield seed layer 304. First half-gap layer 308 is then formed on bottom shield layer 306. Then, a series of depositions, etching, milling and lift-off processes are performed to fabricate read element 310 on top of the first half-gap layer 308. The read element 310 may be a magnetoresistive (MR) sensor, a multilayer device operable to sense magnetic fields from the magnetic medium. The read element 310 may be any one of a plurality of MR-type sensors, including, but not limited to, AMR (anisotropic magnetoresistive), GMR (giant magnetoresistive), TMR (tunnel magnetoresistive), and spin valve. At least one layer of the read element 310 is a sensing layer, such as a free layer of a GMR spin valve sensor that requires longitudinal biasing. A second half-gap layer 312 is deposited on top of the read element 310 and the first half gap-layer 308. The first and second half-gap layers 308 and 312, respectively, isolate the read element 310 from the layers 314 and 316 and the bottom shield layer 306.

A shared pole seed layer 314 is deposited on top of the second half-gap layer 312. A shared pole layer 316 is deposited on top of shared pole seed layer 314. In a merged read/write head configuration, layers 314 and 316 serve as flux shields for read element 310 and also as a bottom pole (or a “return pole”) for the write portion of the head 300, which provides a shared shield/pole structure. A writer gap layer 318 is formed on top and at a pole tip end of the shared pole layer 316, where the pole tip end of the shared pole layer 316 is the end closest to the ABS 301. Also, a coil insulator 324 is formed on top and away from the pole tip end of the shared pole layer 316. The coil insulator 324 typically includes multiple insulator layers. An arrangement of conductive coils 326 are deposited in between layers of the coil insulator 324. The top pole of the write head portion of the merged read/write head 300 is then formed by depositing an optional top pole seed layer 320 on top of the writer gap layer 318 and the coil insulator 324. Finally, a top pole layer 322 is deposited on the top pole seed layer 320, if present, or may be sputtered directly on the writer gap layer 318. The top pole layer 322 is also known as the “write pole” or the “main pole.”

In order to write to a magnetic medium, a time-varying electrical current, also known as a write current, is caused to flow through the conductive coils 326 of the read/write head 300. The write current produces a time-varying magnetic field through the top pole layer 322 and the shared pole layer 316. The top pole layer 322 and shared pole layer 316 are generally opposite poles, thus the magnetic field flows from the top pole layer 322 to the shared pole layer 316. The magnetic medium is passed near the ABS 301 of the read/write head 300 at a predetermined distance such that a magnetic surface of the medium passes through the magnetic field. The top pole layer 322 is the actual writing pole that actively magnetizes the adjacent bit areas on the magnetic medium, while the shared pole layer 316 completes a magnetic flux path from the top pole layer 322. It is desirable for the top pole layer 322, or at least the top pole layer 322 tip (closest to the ABS 301), to be formed of an alloy exhibiting a relatively high saturation magnetization (B_{S}) in order to generate a high magnetic field in the magnetic medium, which may thereby increase the data density of the magnetic medium. In addition, narrower pulse widths, smaller erase bands, and straighter transitions for given media properties are possible if materials with high saturation magnetization are used for the top pole layer 322.

The high saturation magnetization (B_{S}) alloys described in this disclosure may be used in any portion of the read/write head 300, but typically are used for a pole layer such as, for example, the top pole layer 322. In addition, the composition and magnetic properties of the other layers of the head 300, such as, for example, the top pole seed layer 320, may be selected to modify or enhance the magnetic properties, corrosion resistance, thermal stability and the like of the alloys used in the top pole layer 322. For example, suitable materials for use in the top pole seed layer 320 are described, for example, in U.S. Pat. No. 6,562,487, which is entirely incorporated herein by reference.

When used in a magnetic recording head such as the read/write head 300, the alloys and alloy films described herein provide improved corrosion resistance as compared to conventional high saturation magnetization materials, such as FeCo. Two relevant measurements of corrosion resistance are the corrosion potential (E_{Corr}) and corrosion current density (I_{Corr}) of the film. High values (less negative) for the E_{Corr} are preferred, while low current density I_{Corr} values are also desired.

### EXAMPLES

Various embodiments of the alloys will now be described in reference to the following examples. These examples are provided for illustrative purposes.

### Example 1

Si wafers deposited with SiO₂ in a thickness of about 3 Angstroms (Å) (0.0003 micrometers (μm)) were used as substrates. Samples of pure Fe, Co and dopant metals selected from Pd, Pt, Ru, and Rh were prepared by sputter deposition from elemental and/or alloy targets. The alloy samples were then applied onto the substrates using a sputter deposition process known in the art, which was conducted in a vacuum and at an ambient temperature. Thin films composed of the alloy were deposited in a thickness of about 500 to about 1000 Å (about 0.05 to about 0.1 μm).

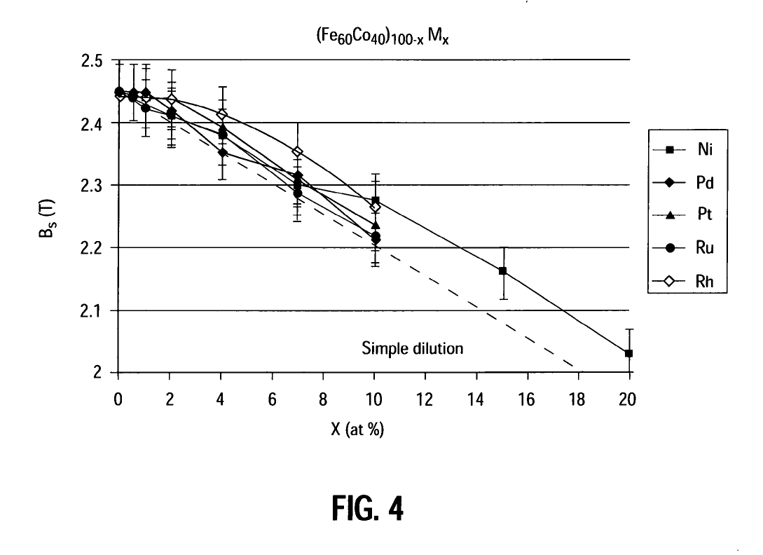

FIG. 4 is a plot showing the saturation magnetization (Bₛ) of the various alloys having the general formula (Fe₆₀CO₄₀)₁₀₀₋ₓMₓ, where M includes one element of a group including Ni, Pd, Pt, Ru, and Rh, and where 5<x≦20. As illustrated in FIG. 4, when x≦20, the alloys have very high saturation magnetizations of Bₛ>2.0 T, which are comparable to B_{S} values of conventional FeCo and FeCoNi alloys. However, in contrast to conventional FeCo and FeCoNi alloys, the FeCo alloys doped with a metal in accordance with the present invention exhibit substantially improved corrosion resistance, as described in reference to Examples 2 and 3. More specifically, it was found that where x>5, the corrosion resistance of the alloy is substantially improved as compared to conventional FeCo and FeCoNi alloys. It is believed the (Fe₆₀CO₄₀)₁₀₀₋ₓMₓ alloys, where M is Os or Ir exhibit substantially similar properties as those shown in the plot of FIG. 4 because of the shared metal characteristics.

### Example 2

Various alloys were prepared using the processes described in Example 1. The saturation magnetization, corrosion potential (E_{Corr}) and corrosion current density (I_{Corr}) values for the alloys were measured and compared to conventional FeCo alloys.

The corrosion potential and corrosion current density were measured in two solutions: (1) an electrolyte solution of 0.1 M NaCl having a pH of approximately 5.9; and (2) an electrolyte solution of 0.1 M NaCl having a pH of approximately 3.0. The pH 5.9 NaCl solution was selected to simulate some of the wet-chemistry environments encountered by a read write head during manufacture, and is also used to mimic conditions of humidity when drives are being tested. The pH 3.0 NaCl solution was used to simulate some of the harsher wet-processes the read write head is exposed to during manufacture.

The corrosion tests were carried out using a Gamry Potentiostat. The electrochemical cell was an EG&G flat cell (available from Princeton Applied Research) onto which a wafer was clamped to expose 1 cm² of a metal film to approximately 300 ml of solution. All the solutions were used in their naturally aerated state and they were quiescent (unstirred). Scans of metal film potential relative to a standard SCE (saturated calomel electrode) versus log (current density) were carried out at 1.0 mV per second. The scans were started after the films were exposed to the solutions and the potential reached a stable value.

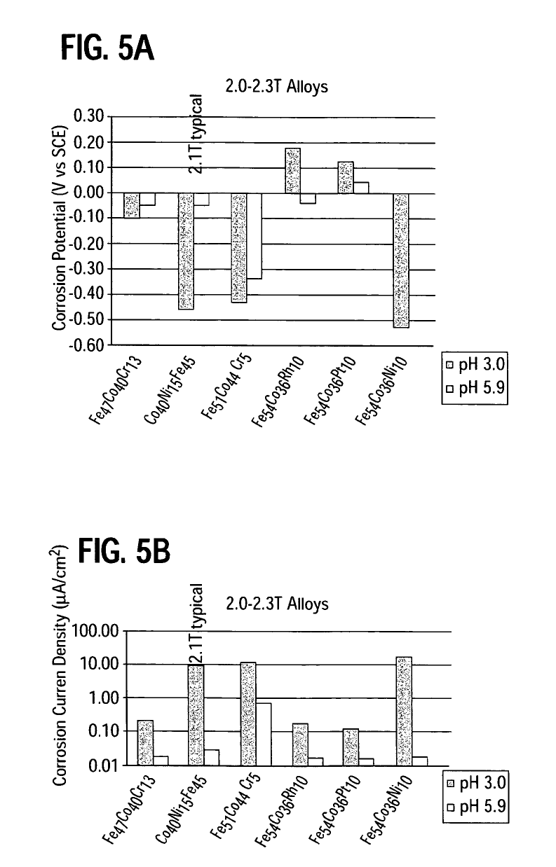

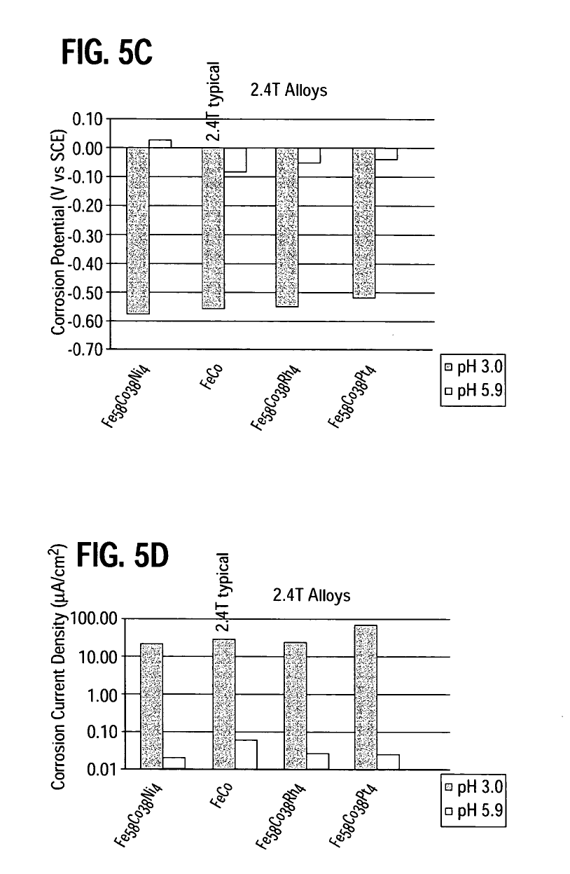

The corrosion current densities I_{Corr} were determined by computer Tafel analyses. I_{Corr} values are proportional to the corrosion rates and should be taken as order of magnitude determinations. The E_{Corr} value in a solution is the potential of the metal film versus an SCE with no net current flowing. The corrosion potential (E_{Corr}) and corrosion current density (I_{Corr}) values for FeCo and various FeCoM alloys measured in 0.1 M NaCl solution are shown in Table 1 below and in FIGS. 5A-5D.

TABLE 1

| | | | | pH 3.0 | | pH 5.9 | |
|---|---|---|---|---|---|---|---|
| | | | | E_{Corr} | | E_{Corr} | |
| Alloy | | Composition | | V vs | I_{corr} | V vs | I_{corr} |
| (at %) | Dep | (at %) | Bₛ (T) | SCE | μA/cm² | SCE | μA/cm² |
| Fe₄₇Co₄₀Cr₁₃ | Spt SFI | (Fe₅₄Co₄₆)Cr₁₃ | 2.00 | −0.10 | 0.20 | −0.05 | 0.02 |
| Co₄₀Ni₁₅Fe₄₅ | Sput CVC | Co₄₀Ni₁₅Fe₄₅ | 2.10 | −0.46 | 10 | −0.05 | 0.03 |
| Fe₅₁Co₄₄Cr₅ | Spt SFI | (Fe₅₄Co₄₆)Cr₅ | 2.20 | −0.43 | 13 | −0.33 | 0.80 |
| Fe₅₄Co₃₆Rh₁₀ | Spt SFI | (Fe₆₀Co₄₀)Rh₁₀ | 2.25 | 0.18 | 0.20 | −0.04 | 0.02 |
| Fe₅₄Co₃₆Pt₁₀ | Spt SFI | (Fe₆₀Co₄₀)Pt₁₀ | 2.25 | 0.13 | 0.15 | 0.05 | 0.02 |
| Fe_{M}Co₃₆Ni₁₀ | Spt SFI | (Fe₆₀Co₄₀)Ni₁₀ | 2.27 | −0.53 | 20 | 0.00 | 0.02 |
| Fe₅₈Co₃₈Ni₄ | Spt SFI | (Fe₆₀Co₄₀)Ni₄ | 2.37 | −0.58 | 20 | 0.03 | 0.02 |
| Fe₆₀Co₄₀ | Sput | FeCo | 2.40 | −0.56 | 30 | −0.08 | 0.06 |
| Fe₅₈Co₃₈Rh₄ | Spt SFI | (Fe₆₀Co₄₀)Rh₄ | 2.40 | −0.55 | 25 | −0.05 | 0.03 |
| Fe₅₈Co₃₈Pt₄ | Spt SFI | (Fe₆₀Co₄₀)Pt₄ | 2.40 | −0.52 | 80 | −0.04 | 0.03 |

As indicated in Table 1 and FIGS. 5A-5D, the corrosion resistance of the metal doped FeCo alloys greatly increased over the pure FeCo alloys. The less negative E_{Corr} values of the FeCoM alloys shows a greater resistance to the onset of corrosion and the smaller values of I_{Corr} correspond to the lower corrosion rates of these alloys. For example, the Fe₅₄Co₃₆Pt₁₀ alloy in accordance with the present invention exhibits I_{CORR} values of 0.15 μA/cm² at a pH of 3.0 and 0.02 μA/cm² at a pH of 5.9 as compared the I_{CORR} values of 30 μA/cm² at a pH of 3.0 and 0.06 μA/cm² at a pH of 5.9 for the conventional Fe₆₀Co₄₀ alloy. The Fe₅₄Co₃₆Pt₁₀ alloy also exhibits improved E_{corr} values of about 0.13 V at a pH of 3.0 and 0.05 V at a pH of 5.9, as compared to −0.56 V at a pH of 3.0 and −0.08 V at a pH of 5.9 for the conventional Fe₆₀CO₄₀ alloy. As previously described, a higher E_{corr} value for is desirable. In addition to the improved corrosion resistance and corrosion potential, the Fe₅₄Co₃₆Pt₁₀ alloy in accordance with the present invention exhibits a relatively high saturation magnetization of 2.25 T, which is comparable in performance to the conventional Fe₆₀Co₄₀ alloy exhibiting a saturation magnetization of 2.40 T.

### Example 3

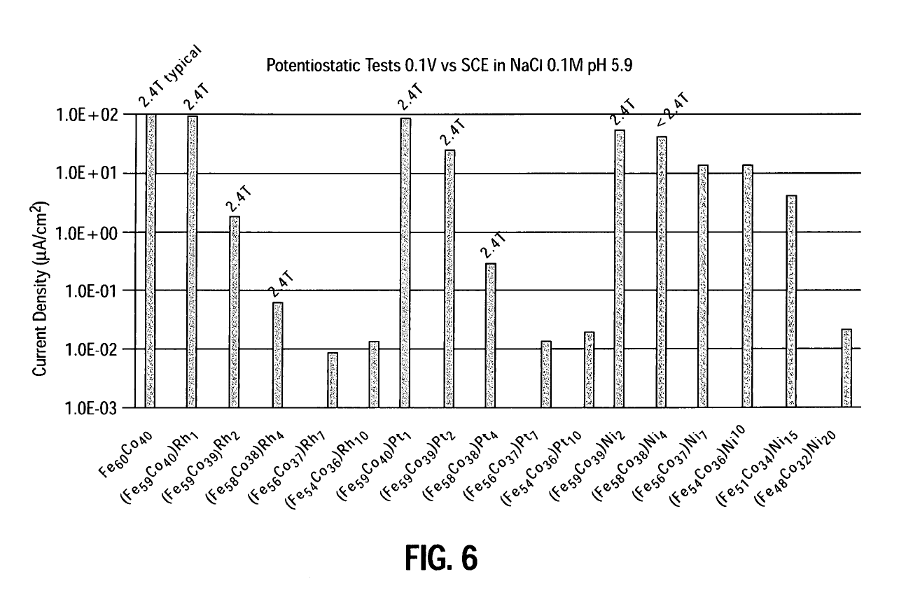

Various FeCoM alloys were prepared using the procedures outlined in Example 1. The current density values for FeCo and various FeCoM alloys were also measured at a potential of +0.1 V versus SCE in an electrolyte solution of 0.1 M NaCl having a pH of approximately 5.9. The results of this testing are provided below in Table 2 and in FIG. 6.

TABLE 2

| Alloy Composition | I_{corr} |
|---|---|
| (at %) | μA/cm² |
| Fe₆₀Co₄₀ | 100.0 |
| (Fe₅₉Co₄₀)Rh₁ | 84.0 |
| (Fe₅₉Co₃₉)Rh₂ | 1.60 |
| (Fe₅₈Co₃₈)Rh₄ | 0.06 |
| (Fe₅₆Co₃₇)Rh₇ | 0.008 |
| (Fe₅₄Co₃₆)Rh₁₀ | 0.013 |
| (Fe₅₉Co₄₀)Pt₁ | 80.0 |
| (Fe₅₉Co₃₉)Pt₂ | 25.0 |
| (Fe₅₈Co₃₈)Pt₄ | 0.30 |
| (Fe₅₆Co₃₇)Pt₇ | 0.013 |
| (Fe₅₄Co₃₆)Pt₁₀ | 0.018 |
| (FC₅₉CO₃₉)Ni₂ | 50.0 |
| (Fe₅₈Co₃₈)Ni₄ | 40.0 |
| (Fe₅₆Co₃₇)Ni₇ | 13.0 |
| (Fe₅₄Co₃₆)Ni₁₀ | 13.0 |
| (Fe₅iCo₃₄)Ni₁₅ | 4.0 |
| (Fe₄₈Co₃₂)Ni₂₀ | 0.02 |

As indicated in Table 2 and FIG. 6, again the current density I_{Corr} of the metal doped FeCo alloys are lower than the current density the pure cobalt iron (Fe₆₀CO₄₀) alloy, which indicates that the metal doped cobalt iron alloys exhibit a lower rate of corrosion than the pure cobalt iron (Fe₆₀Co₄₀) alloy. For example, the alloy (Fe₅₄Co₃₆)Rh₁₀ in accordance with the present invention exhibits a substantially lower I_{CORR} value of 0.013 μA/cm² as compared to 100 μA/cm² for the pure Fe₆₀Co₄₀ alloy. Table 2 and FIG. 6 also demonstrate the current density I_{Corr} of the alloy improves in alloys comprising a metal (Rh or Pt in Table 2) in greater than 5 at %. For example, an alloy comprising 1 at % of Pt ((Fe₅₉Co₄₀)Pt₁) exhibits a current density I_{Corr} of 80.0 μA/cm², whereas when the atomic percentage of Pt is increased to 7, the current density I_{Corr} decreases to 0.013 μA/cm².

The present invention should not be considered limited to the particular examples described above, but rather should be understood to cover all aspects of the invention as fairly set out in the attached claims. Various modifications, equivalent processes, as well as numerous structures to which the present invention may be applicable will be readily apparent to those of skill in the art to which the present invention is directed upon review of the instant specification.

1. An alloy with the formula Fe_{A}Co_{B}M_{C}, wherein M includes at least one element of Rh, Ru, Pt, Pd, Os, and Ir, wherein 48≦A<60, 30≦B≦50 and 5<C≦20, and wherein A+B+C=about 100 at %.

2. The alloy of claim 1, wherein 55≦A≦60, 35≦B≦40 and 5<C≦10, and wherein A+B+C=about 100 at %.

3. The alloy of claim 1, wherein 55≦A≦60, 35≦B≦40 and 8≦C≦12, and wherein A+B+C=about 100 at %.

4. A film comprising the alloy of claim 1, wherein the film has a thickness of 0.005 μm to 0.5 μm.

5. The film of claim 4, wherein the film is sputter deposited.

6. The film of claim 4, wherein the film comprises less than about 0.20 at % of an impurity.

7. The film of claim 6, wherein the impurity is at least one of H, N, O, S, Cl, F, and C.

8. The film of claim 4, wherein the film is at least a part of a write pole of a magnetic read/write head.

9. The alloy of claim 1, wherein the alloy has the formula (Fe₆₀Co₄₀)₁₀₀₋ₓMₓ, and wherein 5<x≦20.

10. An alloy with the formula Fe_{A}Co_{B}M_{C}, wherein M includes at least one element of Rh, Ru, Pt, Pd, Os, and Ir, wherein 50≦A≦70, 35<B≦50 and 5<C≦20, and wherein A+B+C=about 100 at %.

11. The alloy of claim 10, wherein 55≦A≦65, 35≦B≦40 and 5<C≦10, and wherein A+B+C=about 100 at %.

12. The alloy of claim 10, wherein 55≦A≦65, 35≦B≦40 and 8≦C≦12, and wherein A+B+C=about 100 at %.

13. A film comprising the alloy of claim 10, wherein the film has a thickness of 0.005 μm to 0.5 μm.

14. The film of claim 13, wherein the film is sputter deposited.

15. The film of claim 13, wherein the film is at least a part of a write pole of a magnetic read/write head.

16. The film of claim 13, wherein the film is disposed in a write pole of a magnetic read/write head.

17. A process of forming a thin film, the process comprising depositing metals selected from a group including Fe, Co, Rh, Ru, Pt, Pd, Os, and Ir to form an alloy with the formula Fe_{A}Co_{B}M_{C}, wherein M is at least one element of Rh, Ru, Pt, Pd, Os, and Ir, and wherein 50≦A≦70, 35<B≦50 and 5<C≦20, and wherein A+B+C=about 100 at %.

18. The process of claim 17, wherein the metals are deposited using a method selected from a group consisting of electroplating and physical vapor deposition.

19. The process of claim 18, wherein the metals are deposited using a sputter deposition method.

20. The process of claim 17, wherein the alloy comprises less than about 0.20 at % of an impurity.
